(19) United States
(12) Patent Application Publication
(10) Pub. No.: US 2025/0067509 A1
(43) Pub. Date: Feb. 27, 2025

(54) DRYER TOOL AND OPERATION METHOD THEREOF

(71) Applicants: TAIWAN SEMICONDUCTOR MANUFACTURING COMPANY, LTD., Hsinchu (TW); TSMC CHINA COMPANY LIMITED, Shanghai (CN)

(72) Inventors: Hui CAO, Shanghai City (CN); Jiyong ZHANG, Shanghai City (CN); Tao ZHU, Shanghai City (CN)

(73) Assignees: TAIWAN SEMICONDUCTOR MANUFACTURING COMPANY, LTD., Hsinchu (TW); TSMC CHINA COMPANY LIMITED, Shanghai (CN)

(21) Appl. No.: 18/479,106

(22) Filed: Oct. 1, 2023

(30) Foreign Application Priority Data
Aug. 24, 2023 (CN) 202322282380.X

(51) Int. Cl. F26B 11/00; F26B 21/10

(52) U.S. Cl. CPC F26B 11/00; F26B 21/10; F26B 2210/00

(57) ABSTRACT

A method includes placing a ring-shaped bearing on a cylindrically-shaped sidewall in a chamber, the ring-shaped bearing comprising an inner race, an outer race, balls between the inner race and the outer race, and a grease among the balls; rotating the outer race of the ring-shaped bearing while the inner race of the ring-shaped bearing remains stationary relative to the cylindrically-shaped sidewall; heating the ring-shaped bearing; pumping the grease out of the chamber.

### BACKGROUND

The present application claims priority to China Application Serial Number 202322282380.X, filed on Aug. 24, 2023, which is herein incorporated by reference.

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

The use of robot arms is an established manufacturing expedient in applications where human handling is inefficient and/or undesired. For example, in the semiconductor arts robot arms are used to handle wafers during various process steps. Such process steps include those which occur in a reaction chamber, e.g. etching, deposition, passivation, etc., where a sealed environment must be maintained to limit the likelihood of contamination and to ensure that various specific processing conditions are provided.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a schematic top view of a vacuum processing system having multiple wafer handlers in accordance with some embodiments of the present disclosure.

FIG. 1B illustrates a schematic perspective view of a wafer handler in accordance with some embodiments of the present disclosure.

FIG. 1C illustrates a schematic cross-sectional view of a mechanism for manipulating a wafer handler in accordance with some embodiments of the present disclosure, in which the mechanism includes a cylindrical sidewall, magnet rings, and ring-shaped bearings between the cylindrical sidewall and the magnet rings.

FIGS. 1D and 1E illustrate a cross-sectional view and a structural analysis diagram of a ring-shaped bearing in accordance with some embodiments of the present disclosure.

FIGS. 2A-2D illustrate schematic perspective views and a top view of a dryer tool with ring-shaped bearings in accordance with some embodiments of the present disclosure.

FIG. 2E is a cross-sectional view obtained from the reference cross-section E-E′ in FIGS. 2A-2D.

FIG. 2F is a schematic top view of a liner used in a dryer tool in accordance with some embodiments of the present disclosure.

FIGS. 2G and 2H illustrate schematic cross-sectional views of dryer tools with ring-shaped bearings corresponding to FIGS. 2A-2E.

FIGS. 3A-3C are diagrams plotting measured pressure in a chamber of a dryer tool versus time in accordance with some embodiments of the present disclosure.

FIG. 4 is a flowchart of a method of using a dry tool to dry ring-shaped bearings in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may mean within 20 percent, or within 10 percent, or within 5 percent of a given value or range. One skilled in the art will realize, however, that the value or range recited throughout the description are merely examples, and may be reduced with the down-scaling of the integrated circuits. Numerical quantities given herein are approximate, meaning that the term “around,” “about,” “approximately,” or “substantially” can be inferred if not expressly stated.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In order to carry out different processes on the wafer, a wafer handler is installed in the buffer chamber to transfer the wafer to the different process chambers. Bearings are installed in the wafer handler to provide a smooth and low-friction surface for the lower and upper magnet rings in the wafer handler to rotate against, allowing for more efficient and reliable operation of the wafer handler, and these bearings will need to be replaced (e.g., annual) periodically as they wear out. However, due to the low-pressure environment (e.g., about 1×10e−6 to about 1×10e−10 Torr) required for the buffer chamber of the vacuum processing system to operate, excessive lubricant/grease on the bearing in the buffer chamber may take a considerable amount of time to fully evaporate and diffuse in the buffer chamber after the installation of the bearing, especially following repairs to the vacuum processing system. As a result, the pressure in the buffer chamber may take longer than expected to decrease to the required low-pressure level.

Therefore, the present disclosure in various embodiments provides a dryer tool that enables bearings to remove excess lubricant/grease before loading into the buffer chamber of a cluster tool. By doing so, the amount and duration of volatility of the bearings in the buffer chamber can be reduced, and then the buffer chamber can swiftly decrease pressure to reach the working pressure. Specifically, the dryer tool can create a pre-extraction environment for the bearing, which is similar to the buffer chamber of the vacuum processing system. This environment allows the lubricant/grease on the bearing to be vaporized by the dryer tool before the bearing is installed in the buffer chamber. Additionally, the dryer tool utilizes a technique of rotating and heating the bearing to expedite the volatilization of the lubricant/grease from the bearing, such that the dryer tool can help optimize the installation process and improve the performance of the buffer chamber.

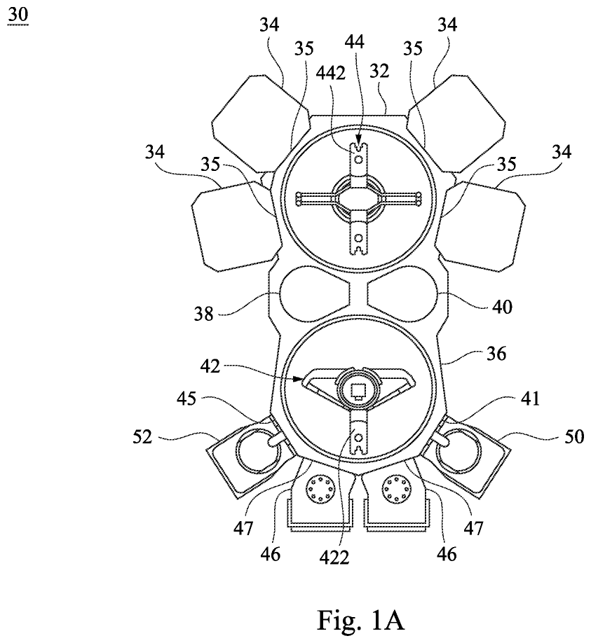

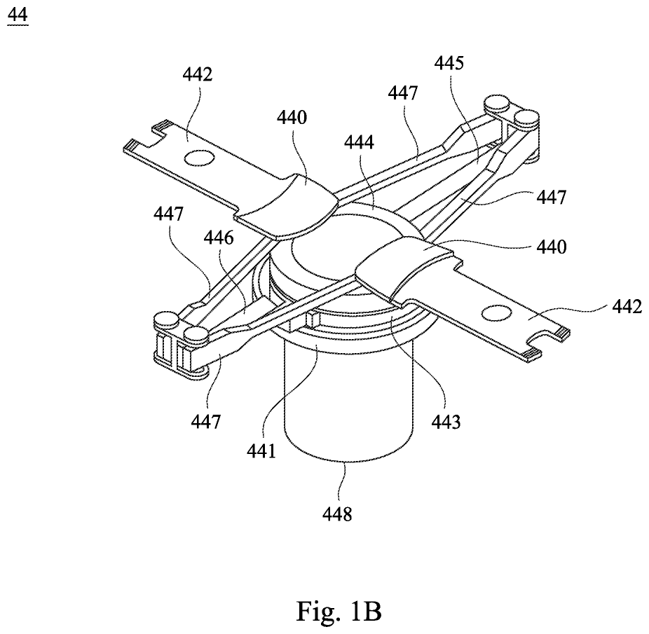

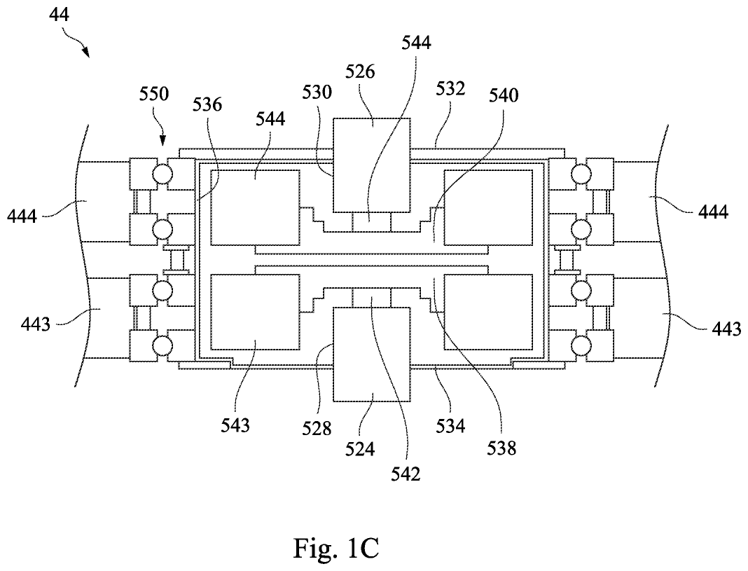

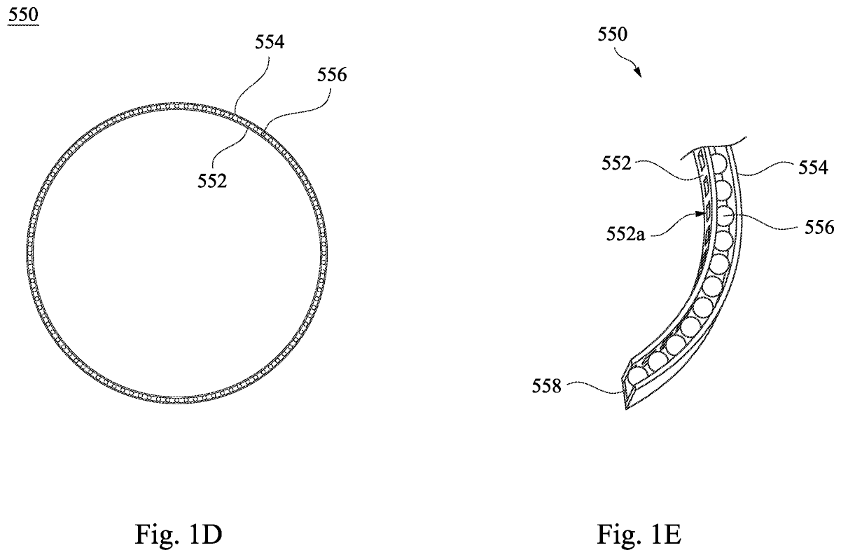

Reference is made to FIG. 1A. FIG. 1A illustrates a schematic top view of a vacuum processing system 30 having multiple wafer handlers 42 and 44 in accordance with some embodiments of the present disclosure. As shown in FIG. 1A, the vacuum processing system 30 includes a buffer chamber 32 and a buffer chamber 36 typically mounted on a platform (not shown) and generally forming a system monolith. The buffer chamber 32 can have four process chambers 34 mounted at facets 35 of the system monolith. The buffer chamber 36 can have a degas chamber 50 mounted at facets 41 of the system monolith, a wafer aligner chamber 52 mounted at facets 45 of the system monolith, and two load lock chambers 46 mounted at facets 47 of the system monolith. The buffer chamber 32 and the buffer chamber 36 each have at least one wafer handler 44 42, or robot, for transferring wafers therethrough. Each of these wafer handlers 44 and 42 has at least one end effector 442/422 designed to hold the wafers. In some embodiments, the buffer chamber 32 or 34 can be interchangeably referred to as a transfer chamber.

The process chambers 34 perform the process on the wafers in the vacuum processing system 30. The process chambers 34 may be any type of process chamber, such as a rapid thermal processing chamber, a physical vapor deposition chamber, a chemical vapor deposition chamber, an etch chamber, etc. The process chambers 34 may be supported by the buffer chamber 32 or may be supported on their own platforms depending on the configuration of the individual process chambers 34. Slit valves (not shown) in the facets 35 provide access and isolation between the buffer chamber 32 and the process chambers 34. Correspondingly, the process chambers 34 have openings (not shown) on their surfaces that align with the slit valves. In some embodiments, the process chamber 34 may a PVD Ti process chamber, PVD TiN process chamber, CVD Al process chamber, or a PVD AlCu process chamber. The specific configuration of the chambers in FIG. 1A is merely illustrative and comprises an integrated processing system capable of both CVD and PVD processes in a single cluster tool.

The degas chamber 50 is for driving off moisture on the wafers if necessary. The wafer aligner chamber 52 is typically attached to the buffer chamber 36 with a wafer aligner disposed therein for receiving the wafers from the wafer handler 42 aligning the wafers before the wafer handler 42 transfers the wafers to the pre-clear chamber 38 or a pre-processing chamber 48. Alternatively, the chambers 38, 40 may both be pass-through/cool-down chambers.

The load lock chambers 46 transit the wafers between the ambient environment pressure to the buffer chamber vacuum pressure. Openings (not shown) in facets 47 provide access and valves provide isolation between the load lock chambers 46 and the buffer chamber 36. Correspondingly, the load lock chambers 46 have openings on their surfaces that align with the openings in facets 47.

The wafer handler 44 is disposed within the buffer chamber 32 for transferring a wafer between the pre-clean chamber 38, the cool-down chamber 40 and the process chambers 34. A similar wafer handler 42 is disposed within the buffer chamber 36 for transferring a wafer between the load lock chambers 46, the degas chamber 50, the wafer aligner chamber 52, the pre-clean chamber 38 and the cool-down chamber 40. The wafer handler 42 is depicted as a single-blade robot, meaning that it has an attachment 420 for only one blade, or end effector 422, and can support only one wafer at a time. The wafer handler 44 is depicted as a dual-blade robot, meaning that it has attachments 440 for two end effectors 442 and can support two wafers at a time. Alternatively, the wafer handlers 42 and 44 may both be single-blade robots or dual-blade robots. The present disclosure may be used with either of these types of wafer handlers and any other appropriate wafer handler.

In some embodiments, a pre-clear chamber 38 and a cool-down chamber 40 may be disposed between the buffer chamber 32 and the buffer chamber 36. The pre-clean chamber 38 cleans the wafers before they enter the buffer chamber 32, and the cool-down chamber 40 cools the wafers after they have been processed in the process chambers 34. The pre-clean chamber 38 and the cooldown chamber 40 may also transition the wafers between the vacuum levels of the buffer chamber 32 and the buffer chamber 36.

Reference is made to FIGS. 1B-1E. FIG. 1B illustrates a schematic perspective view of the wafer handler 44 of the vacuum processing system 30 in accordance with some embodiments of the present disclosure. FIG. 1C illustrates a schematic cross-sectional view of a mechanism for manipulating the wafer handler 44 in accordance with some embodiments of the present disclosure, in which the mechanism includes a cylindrical sidewall 443, magnet rings 444, and ring-shaped bearings 550 between the cylindrical sidewall 443 and the magnet rings 444. FIGS. 1D and 1E illustrate a cross-sectional view and a structural analysis diagram of the ring-shaped bearing 550 in accordance with some embodiments of the present disclosure.

As shown FIG. 1B, the wafer handler 44 can have attachments 440 for two end effectors, or substrate blades, 442, it can support two wafers at a time. Therefore, if each process chambers 34 (see FIG. 1A), pre-clear chamber 38 (see FIG. 1A), and a cool-down chamber 40 (see FIG. 1A) is fully loaded with a wafer, then the wafer handler 44 can have to have a place to temporarily store one wafer in order to transfer another wafer to the spot previously occupied by the first wafer. In some embodiments, the attachment 440 can be interchangeably referred to as a wrist. The wafer handler 44 has a mounting plate 441 for mounting to the bottom of the interior of the chamber in which it resides. Above the mounting plate 441 is a lower magnet ring 443. Above the lower magnet ring 443 is an upper magnet ring 444. The lower and upper magnet rings 443. 444 are magnetically coupled to the lower and upper magnet rings 543 and 544 (see FIG. 1C) and rotate relative to the mounting plate 441 in order to align one of the end effectors 442 with a chamber opening in order to insert or remove a wafer. In some embodiments, the lower and upper magnet rings 443 and 444 can be interchangeably referred to as outer magnet rings or magnetic couplings, and the lower and upper magnet rings 543 and 544 (see FIG. 1C) can be interchangeably referred to as inner magnet rings. Lower and upper pivot arms 445, 446 attach to the lower and upper magnet rings 443 and 444, respectively, and to the struts 447. The struts 447 connect to the attachments 440 for the end effectors 442. The magnet rings 443 and 444 rotate in the same direction in order to rotate the end effectors 442. The lower and upper magnet rings 443 and 444 rotate in opposite directions in order to pivot the pivot arms 445 and 446 in the direction of one of the two end effectors 442 in order to extend that the end effector 442 or retract the opposite end effector 442. In some embodiments, the struts 447 can be interchangeably referred to as leveled arms. Therefore, the mechanism for manipulating the wafer handler 44 can be referred to as a dual blade linkage with individually leveled arms. Below the mounting plate 441 is the motor assembly housing 448 for containing a single-motor assembly for driving the rotation of the lower and upper magnet rings 443 and 444. In some embodiments, the single-motor assembly can be direct drive servo motors.

Reference is made to FIG. 1C. FIG. 1C shows an assembly for activating the rotation of the lower and upper magnet rings 443 and 444 for manipulating the wafer handler 44. The lower and upper motors 524, 526 combined with gear reduction assemblies 528, 530 mount to the top 532 and bottom 534 of a motor assembly housing. A cylindrically-shaped sidewall 536 supports the top 532 and bottom 534 and separates the ambient pressure environment on the inside of the motor assembly housing from the vacuum environment of the buffer chamber 32 (see FIG. 1A). The lower and upper gear reduction assemblies 528 and 530 attach to lower and upper magnet clamps 538 and 540 through drive shafts 542 and 544, respectively. The lower and upper magnet clamps 538 and 540 support lower and upper magnet rings 543 and 544. The lower and upper magnet rings 543 and 544 are magnetically coupled through the cylindrical sidewall 536 to the lower and upper magnet rings 443 and 444, respectively, on the outside of the motor assembly housing. As the inner lower and upper magnet rings 543 and 544 rotate under the force of their respective motors 524 and 526, the outer lower and upper magnet rings 443 and 444 likewise rotate. The two motors 524 and 526 can rotate the inner and outer magnet ring pairs 543, 544, 443, and 444 in the same axial direction or in opposing axial directions in order to rotate, extend or retract the end effectors 442 (see FIGS. 1A and 1B) as described above. The separation of the inner and outer portions of the wafer handler by way of the magnetic coupling through the motor assembly housing effectively prevents particles and contaminants from entering the vacuum of the buffer chamber 32 (see FIG. 1A) and potentially damaging the wafers being transferred therethrough.

As shown in FIG. 1C, a plurality of ring-shaped bearings 550 (e.g., about 4 ring-shaped bearings 550) can be installed (or placed) between the lower and upper magnet rings 443 and 444 and the cylindrically-shaped sidewall 536. Specifically, two ring-shaped bearings 550 are installed between the lower magnet rings 443 and a lower portion of the cylindrically-shaped sidewall 536, and the other two ring-shaped bearings 550 are installed between the upper magnet rings 444 and an upper portion of the cylindrically-shaped sidewall 536. It is noted that the number of the ring-shaped bearings 550 are arranged as illustrated in FIG. 1C, which is for illustrative purposes only and not intended to be limiting beyond what is specifically recited in the claims. The ring-shaped bearing 550 can provide a smooth and low-friction surface for the lower and upper magnet rings 443 and 444 to rotate against, allowing for more efficient and reliable operation of the wafer handler 44. In addition, it can help to ensure precise alignment of the magnet rings, which is crucial for accurate positioning and transfer of the wafers. Furthermore, it can help to minimize wear and tear on the lower and upper magnet rings 443 and 444 and other components of the wafer handler 44, which can extend the lifespan of the equipment and improve the productivity. By way of example and not limitation, the ring-shaped bearing 550 can be a ball ring-shaped bearing.

As shown in FIGS. 1D and 1E. A ring-shaped bearing 550 can be a type of rolling-element bearing that consists of components: an inner race 552, an outer race 554, balls 556 (or rollers) between the inner and outer races 552 and 554, and at least a cover 558 (see FIG. 1E) connecting an edge of one of the inner and outer races 552 and 554 toward an edge of another one of the inner and outer races 552 and 554 to contain the balls 556. To clarify the disclosure, another cover opposite to the cover 558 is omitted. In some embodiments, the inner race 552 can be interchangeably referred to as an inner ring, and the outer race 554 can be interchangeably referred to as an outer ring. The inner race 552 of the ring-shaped bearing 550 is the component that rotates around the bearing's axis. The inner race 552 is a solid, circular piece with a smooth, machined surface to reduce friction between the ring-shaped bearing 550 and the rotating shaft. The outer race 554 is also a circular piece with a smooth surface, and it remains stationary while the inner race 552 rotates around it. The inner and outer races 552 and 554 are separated by a gap that is filled with balls 556 (or rollers). The balls 556 in the ring-shaped bearing 550 are spherical objects that are designed to roll between the inner and outer races 552 and 554 as they rotate. The balls 556 can be made of hardened steel or ceramic and are evenly spaced around the circumference of the ring-shaped bearing 550. The number of balls 556 used in a ring-shaped bearing 550 can vary depending on the size of the bearing 550 and the load it is designed to support. The cover 558 (see FIG. 1E) of the ring-shaped bearing 550 is a thin metal or plastic piece that connects the edges of the inner and outer races 552 and 554 to contain the balls 556. It is designed to keep the balls from falling out of the bearing while still allowing them to roll freely between the inner and outer races 552 and 554. As shown in FIG. 1E, the inner race 552 may have multiple vias 552a thereon. The vias 552a on the inner race 552 of the ring-shaped bearing 550 can be designed to allow lubricant/grease to flow through the ring-shaped bearing 550 and help reduce friction and wear. These vias 552a can be small holes or grooves on the surface of the inner race 552 that provide channels for lubricating oil or grease to flow through. By allowing lubricant/grease to circulate freely through the ring-shaped bearing 550, these vias 552a help reduce friction between the inner and outer races 552 and 554 and the balls 556 (or rollers) that separate them. This, in turn, helps extend the life of the ring-shaped bearing 550 and reduces the risk of damage or failure.

Due to the low-pressure environment (e.g., about 1×10e−6 to about 1×10e−10 Torr) required for the buffer chamber 32 (see FIG. 1A) of the vacuum processing system 30 to operate, excessive lubricant/grease on the ring-shaped bearing 550 may take a considerable amount of time to fully evaporate and diffuse in the buffer chamber 32 after the installation of the ring-shaped bearing 550, especially following repairs to the vacuum processing system 30. As a result, the pressure in the buffer chamber 32 may take longer than expected to decrease to the required low-pressure level.

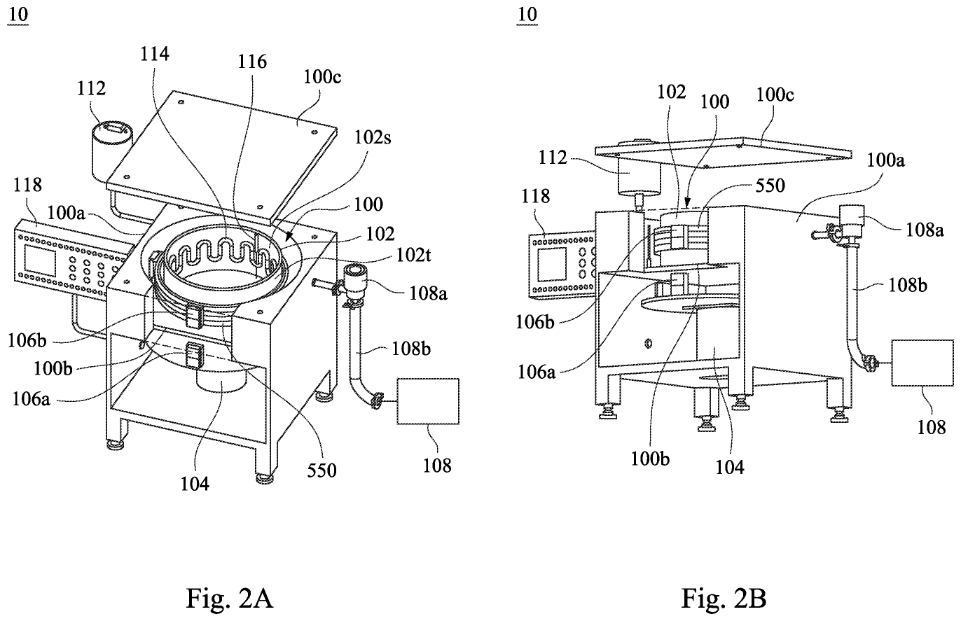

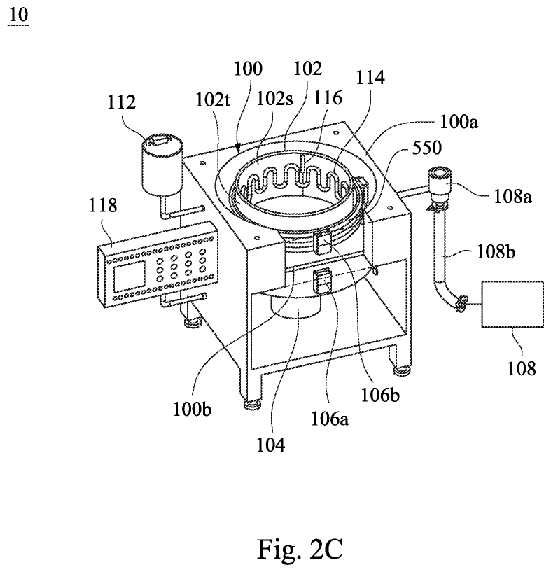

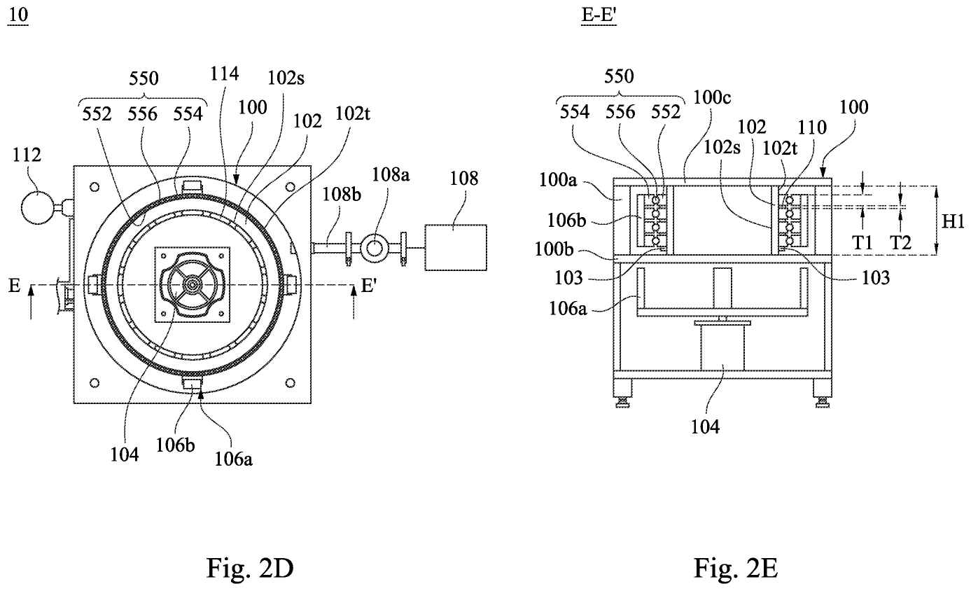

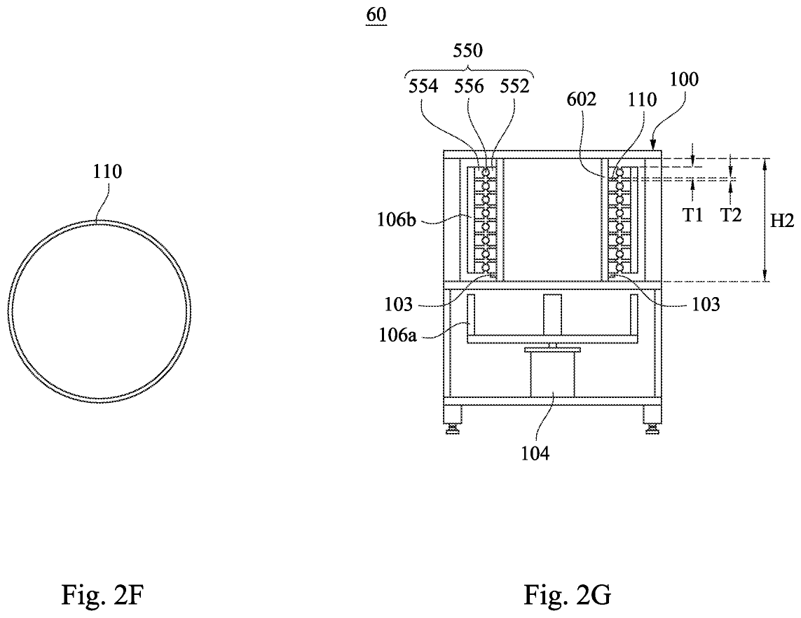

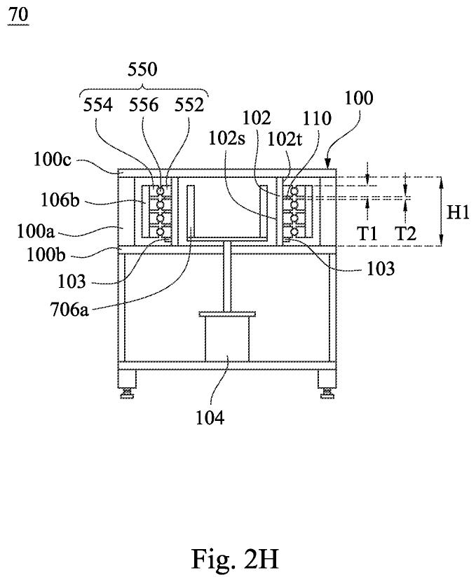

Therefore, this disclosure presents a dryer tool 10 (see FIGS. 2A-2F) that enables bearings 550 to remove excess lubricant/grease before loading into the buffer chamber 32 (see FIG. 1A). By doing so, the amount and duration of volatility of the ring-shaped bearings 550 in the buffer chamber 32 can be reduced, and then the buffer chamber 32 can swiftly decrease pressure to reach the working pressure (e.g., about 1×10e−6 to about 1×10e−10 Torr). Specifically, the dryer tool 10 can create a pre-extraction environment for the ring-shaped bearing 550, which is similar to the buffer chamber 32 of the vacuum processing system 30. This environment allows the lubricant/grease on the ring-shaped bearing 550 to be vaporized by the dryer tool 10 before the ring-shaped bearing 550 is installed in the buffer chamber 32. Additionally, the dryer tool utilizes a technique of rotating and heating the bearing 550 to expedite the volatilization of the lubricant/grease from the ring-shaped bearing 550, such that the dryer tool 10 can help optimize the installation process and improve the performance of the buffer chamber 32.

Reference is made to FIGS. 2A-2F. FIGS. 2A-2C illustrate schematic perspective views of a dryer tool 10 with ring-shaped bearings 550 in accordance with some embodiments of the present disclosure, and to clarify the disclosure, a section of a chamber 100 of the dryer tool 10 has been represented by dotted lines, with a top plate 100c of the chamber 100 separated from the sidewall 100a of the chamber 100. FIG. 2D illustrates a schematic top view of the dryer tool 10 with ring-shaped bearings 550 in accordance with some embodiments of the present disclosure. FIG. 2E is a cross-sectional view obtained from the reference cross-section E-E′ in FIGS. 2A-2D. FIG. 2F is a schematic top view of a ring-shaped liner 110 used in a dryer tool 10 in accordance with some embodiments of the present disclosure. As shown in FIGS. 2A-2E, the dryer tool 10 includes several interconnected structures that work together to remove excess lubricant/grease from the ring-shaped bearing 550 and enable the non-contact rotation of the outer race 554 (see FIGS. 2D and 2E). The dryer tool can include a chamber 100, a cylindrically-shaped sidewall 102 in the chamber 100 for mounting the ring-shaped bearing 550, a motor 104 outside and below the chamber 100, two sets of magnets 106a and 106b, a pump 108, a pressure gauge 112, a heater 114, a thermocouple 116, and a controller 118.

The chamber 100 includes a sidewall 100a, a bottom plate 100b, and a top plate 100c that can separate the vacuum environment around the cylindrically-shaped sidewall 102 from the ambient pressure environment. The cylindrically-shaped sidewall 102 can be mounted in the chamber 100 and is used to hold the ring-shaped bearing 550 during the drying process. The ring-shaped bearing 550 can be installed (or placed) on the cylindrically-shaped sidewall 102 and use a non-contact motor principle to rotate its outer race 554 (see FIGS. 2D and 2E) and fix the inner race 552 (see FIGS. 2D and 2E). That is, the inner race of the ring-shaped bearing 550 is fixed in place on outer surface 102t of the cylindrically-shaped sidewall 102 while allowing the outer race 554 to rotate freely. In other words, the ring-shaped bearing 550 sleeves on the cylindrically-shaped sidewall 102. To fit the ring-shaped bearing 550 onto the cylindrically-shaped sidewall 102 of the dryer tool 100, a support structure 103 (see FIG. 2E) is needed to hold the ring-shaped bearing 550 in place. The support structure 103 can be in the form of a fixture or a specialized tool that is designed to hold the bearing securely in place during installation. In some embodiments, the cylindrically-shaped sidewall 102 can be interchangeably referred to as a cylinder.

In some embodiments, in the case where multiple ring-shaped bearings 550 are installed on the cylindrically-shaped sidewall 102, a ring-shaped liner 110 (see FIGS. 2E and 2F) is placed between two adjacent ring-shaped bearings 550 to separate them. When installing multiple ring-shaped bearings 550 on the cylindrically-shaped sidewall 102, a ring-shaped liner 110 is used to separate the ring-shaped bearings 550. The ring-shaped liner 110 is placed between two adjacent ring-shaped bearings 550 and only touches the inner race 552 (see FIG. 2E) of each ring-shaped bearing 550. Specifically, at least one of the ring-shaped bearing 550 is alternately sleeved on the cylindrically-shaped sidewall 102 with at least one of the ring-shaped liner 110. Therefore, the ring-shaped liner 110 can help to prevent the ring-shaped bearings 550 from rubbing against each other and causing damage or excessive wear. In some embodiments, the ring-shaped liner 110 has a thickness T2 (see FIG. 2E) thinner than a thickness Tl (see FIG. 2E) of the inner race 552 of the ring-shaped bearing 550. In some embodiments, the ring-shaped liner 110 may be made of a same material as the inner race 552 of the ring-shaped bearing 550. In some embodiments, the ring-shaped liner 110 may be made of a different material than the inner race 552 of the ring-shaped bearing 550.

To remove excess lubricant, the dryer tool 10 is equipped with a pump 108 to pre-simulate the pumping environment similar to the buffer chamber 32, allowing the excess lubricant/grease to be removed. In some embodiments, the pressure of the pumping environment in the chamber 100 may be less than the buffer chamber 32 (see FIG. 1A). The pump 108 is connected to the chamber 100 through a valve 108a that controls the flow of air into and out of the chamber 100, and a gas line 108b connects the pump 108 to the chamber 100. The pump 108 is used to evacuate (or exhaust) the chamber 100 and create a vacuum environment in the chamber 100 during the drying process. To remove excess lubricant/grease before loading into the buffer chamber 32 (see FIG. 1A), the dryer tool 10 can simulate the pumping environment similar to the buffer chamber 32 by creating a low-pressure environment. The excess lubricant/grease will evaporate under this low-pressure environment, leaving behind a thin film of lubricant/grease on the ring-shaped bearing 550. In some embodiments, the pump 108 can be a factory vacuum pump. In some embodiments, the pump 108 can continuously pump the chamber 100. In some embodiments, the pump 108 can intermittently pump the chamber 100, with intervals ranging from about every 0.5 seconds to 5 seconds, such as about 0.5, 1, 2, 3, 4, or 5 seconds, depending on the monitored pressure in the chamber 100. The dryer tool 10 can be equipped with the pressure gauge 112. The pressure gauge 112 can be in gas communication with the chamber 100 to monitor the pressure inside the chamber 100.

To remove excess lubricant/grease using the dryer tool 10, the following steps can be taken: Mount the ring-shaped bearing 550 on the cylindrically-shaped sidewall 102 in the chamber 100 of the dryer tool 10. Close the chamber 10 and connect the vacuum pump 108 to the dryer tool 10. Turn on the vacuum pump 108 and begin to evacuate the chamber 100. The pressure gauge 112 can be monitored to ensure that the pressure inside the chamber 100 is at the desired level. Once the desired pressure is achieved, turn off the vacuum pump 112 and open the chamber 100. The ring-shaped bearing 550 can now be loaded into the buffer chamber 32 with the desired amount of lubricant/grease remaining on the ring-shaped bearing 550. By using the dryer tool 10 to remove excess lubricant, the amount of lubricant/grease transferred into the buffer chamber 32 can be controlled more precisely, reducing the risk of over-lubrication and potential contamination of the vacuum system.

In some embodiments, by turning the ring-shaped bearing in the dryer tool, the time required to remove excess lubricant/grease can be improved. As shown in FIGS. 2A-2E, there are two sets of magnets 106a and 106b in the dryer tool 10, one set 106a is located on the motor 104 and the other set 106b is attached to the outer race 554 (see FIGS. 2D and 2E) of the ring-shaped bearing 550. In some embodiments, the first set of magnets 106a on the motor 104 can be interchangeably referred to as a first magnet assembly, the second set of magnets 106b on the ring-shaped bearing 550 can be interchangeably referred to as a second magnet assembly. The magnets 106a and 106b are arranged in such a way that they repel or attract each other, creating a non-contact rotation of the outer race 554. This arrangement allows the outer race 554 to rotate without making contact with the motor 104, thus achieving non-contact rotation. In other words, the motor 104 is responsible for rotating the outer race 554, which in turn causes the inner race 552 (see FIGS. 2D and 2E) to remain fixed in place, enabling the outer race 554 to achieve non-contact rotation. In some embodiments, the motor 104 can be interchangeably referred to as a contact-free bearing rotation motor. As shown in FIG. 2D, the magnets 106b are set to be corresponded to the magnets 106a and overlap the magnets 106a. From the top view, the magnets 106b are around the cylindrically-shaped sidewall 102, and the magnets 106a are also around the cylindrically-shaped sidewall 102.

In some embodiments, the magnets 160b can be attached to the outer race 554 (sec FIGS. 2D and 2E) of the ring-shaped bearing 550 using a variety of methods, depending on the specific design of the ring-shaped bearing 550 and the dryer tool 10. By way of example and not limitation, a mechanical attachment, such as screws, to attach the magnet 106b to the outer race 554. The screws should be carefully designed to avoid damaging the outer race 554 or interfering with its rotation. Alternatively, an adhesive can be used to attach the magnet 106b to the outer races 554. The adhesive should be chosen carefully to ensure that it can withstand the high temperatures and harsh operating conditions of the dryer tool 10. In some embodiments, the magnet 106b may be integrated directly into the outer race 554 of the ring-shaped bearing 550 during manufacturing. In this case, no additional attachment method is necessary, and the magnet 106b will already be in place when the ring-shaped bearing 550 is installed on the cylindrically-shaped sidewall 102 of the dryer tool 10.

To make the outer race 554 (see FIGS. 2D and 2E) of the ring-shaped bearing 550 rotate in a non-contact way and remove excess lubricant/grease using the dryer tool 10, the following steps can be taken: Mount the ring-shaped bearing 550 on the cylindrically-shaped sidewall 102 in the chamber 100 of the dryer tool 10. Close the chamber 10 and connect the vacuum pump 108 to the dryer tool 10. Turn on the vacuum pump 108 and begin to evacuate the chamber 100. Turn on the motor 104 located under the chamber 100 of the dryer tool 10. The motor 104 is equipped with a set of magnets 106a. The outer race 554 of the ring-shaped bearing 550 is also equipped with a set of magnets 106b. When the motor 104 is turned on, the magnetic fields of the magnets 106a and 106b on the motor 104 and the outer race 554 interact with each other, causing the outer race 554 to rotate. As the outer race 554 rotates, the lubricant/grease on it can be exposed to the air inside the chamber 100 and cause the lubricant/grease to vaporize. The vaporized lubricant/grease then flows out of the chamber 100, leaving the outer race 554 of the ring-shaped bearing 550 dry and ready for use. The pressure gauge 112 can be monitored to ensure that the pressure inside the chamber 100 is at the desired level. Once the desired pressure is achieved, turn off the vacuum pump 112 and open the chamber 100. The ring-shaped bearing 550 can now be loaded into the buffer chamber 32 (see FIG. 1A) with the desired amount of lubricant/grease remaining on the ring-shaped bearing 550. It is noted that the non-contact rotation of the outer race 554 is made possible by the magnetic fields of the magnets 106a and 106b, which create an air gap between the outer race 554 and the motor 104. This means that there is no physical contact between the two, resulting in a smooth and efficient rotation of the outer race 554.

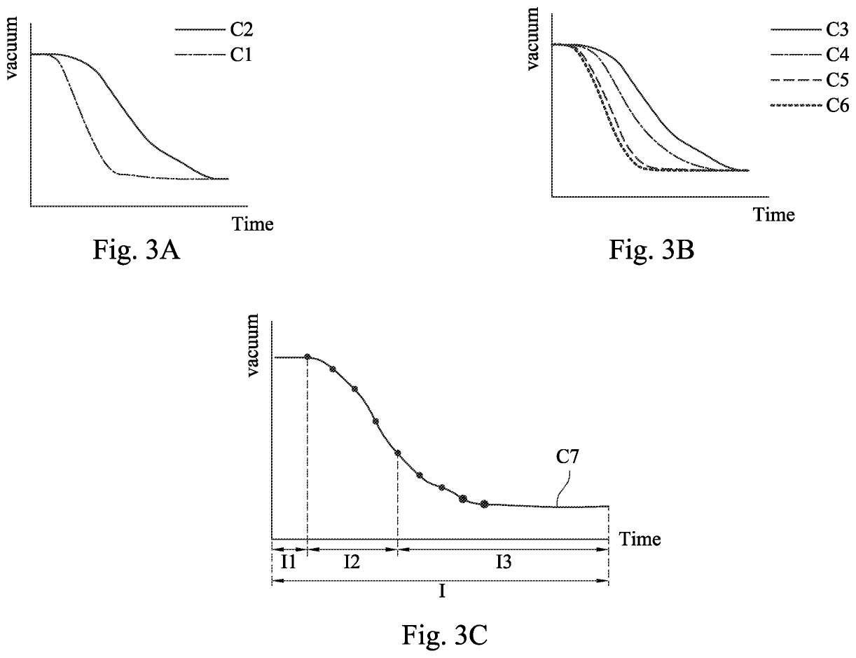

When the ring-shaped bearing 550 is monitored in the dryer tool 10 by turning it, the pressure drop is faster than that without turning, especially in the early stages of the drying process. This is because the rotation of the outer race 554 of the ring-shaped bearing 550 can cause the lubricant/grease to spread more evenly, reducing the thickness of the lubricant/grease film and allowing more air to escape. As a result, the pressure in the chamber 100 drops faster. On the contrary, when the ring-shaped bearing 550 is stationary, the pressure drops gradually over time, and the pressure drop rate is relatively slow. The relationship between the pressure drop and time can be represented by curves C1 and C2 as shown in FIG. 3A, which shows that the pressure drops more rapidly with turning the ring-shaped bearing 550 (see the curve C1 in FIG. 3A) than without turning the ring-shaped bearing 550 (see the curve C2 in FIG. 3A). The exact relationship between pressure drop and time will depend on various factors, such as the rotating speed of the ring-shaped bearing 550, the type of lubricant, and the condition of the bearing 550. By way of example and not limitation, by turning the ring-shaped bearing 550 in the dryer tool 10, the time required to remove excess lubricant/grease can be reduced by up to 60% compared to the original of drying without turning. Therefore, the non-contact rotation of the outer race 554 (see FIGS. 1D and 1E) allows the lubricant/grease to spread more evenly, which accelerates the drying process and reduces the time required to remove excess lubricant. By way of example and not limitation, the ring-shaped bearing 550 may have a rotation speed in a range from about 1 revolution per second to about 10 revolutions per second, such as about 1, 2, 3, 4, 5, 6, 7, 8, 9, 10 revolutions per second. In some embodiments, the rotation speed of the ring-shaped bearing 550 is constant. In some embodiments, the rotation speed of the ring-shaped bearing 550 is variation. For example, the rotation speed of the ring-shaped bearing 550 may be gradually increased or decreased. In some embodiments, the rotation speed of the ring-shaped bearing 550 can be determined based on the detected pressure in the chamber 100.

In some embodiments, by heating the ring-shaped bearing 550 in the dryer tool 10, the time required to remove excess lubricant/grease can also be improved. As shown in FIGS. 2A, 2C, and 2D, a heater 114 can be installed on the inner surface 102s of the cylindrically-shaped sidewall 102 to heat the ring-shaped bearing 550. The heater 114 works by transferring heat from the inner surface 102s to the outer surface 102t of the cylindrically-shaped sidewall 102, where the ring-shaped bearing 550 is mounted. This heats the ring-shaped bearing 550 and allows for more efficient removal of excess lubricant. When the ring-shaped bearing 550 is heated in the dryer tool 10, the temperature of the lubricant/grease inside the ring-shaped bearing 550 will increase, which will reduce its viscosity and increase its volatility. As a result, the lubricant/grease can be easily vaporized and removed, leading to a faster pressure drop compared to when the bearing is not heated.

The relationship between the pressure drop and time can be represented by curves C3, C4, C5, and C6 as shown in FIG. 3B, which shows that the pressure drops more rapidly as the heating time increases. Specifically, the curve C3 shows the relationship between pressure drop and time without heating, the curve C4 shows the relationship between pressure drop and time under heating at 50 degrees Celsius, the curve C5 shows the relationship between pressure drop and time under heating at 60 degrees Celsius, and the curve C6 shows the relationship between pressure drop and time under heating at 70 degrees Celsius. The exact relationship between pressure drop and time will depend on various factors, such as the temperature of the heating, the type of lubricant, and the condition of the ring-shaped bearing 550. By way of example and not limitation, by heating the ring-shaped bearing 550 in the dryer tool 10, the time required to achieve a certain pressure drop can be reduced by 50% compared to the original of drying without heating. This can help to increase the efficiency of the process and reduce the time required for maintenance (e.g., annual maintenance) and repair of the vacuum processing system 30. When the ring-shaped bearing 550 is heated to a certain temperature, such as 50 degrees Celsius, 60 degrees Celsius, and 70 degrees Celsius, the pressure drop will increase as the temperature increases. This is because as the temperature increases, the viscosity of the lubricant/grease decreases, leading to a faster flow of the lubricant. This faster flow results in a greater amount of lubricant/grease being removed from the ring-shaped bearing 550, leading to a higher pressure drop. Additionally, at higher temperatures, the lubricant/grease may vaporize more quickly, leading to more efficient removal of excess lubricant. However, it is important to note that excessively high temperatures can damage the ring-shaped bearing 550 or other components, so the temperature must be controlled.

In some embodiments, the heating temperature can be monitored by a thermocouple 116 (see FIGS. 2A and 2C) installed on the inner surface 102s of the cylindrically-shaped sidewall 102 and controlled by a controller 118 (see FIGS. 2A-2C) electrically connected to the heater 114. The controller 118 can be programmed to read and display the temperature data in real-time. By way of example and not limitation, the heating temperature can be in a range from about 60 degrees Celsius to about 90 degrees Celsius, such as about 60, 65, 70, 75, 80, 85, or 90 degrees Celsius. In some embodiments, the heating temperature may be constant. In some embodiments, the heating temperature is variation. For example, the heating temperature may be gradually increased or decreased. In some embodiments, the heating temperature can be determined based on the detected pressure in the chamber 100.

By way of example and not limitation, to ensure safety and prevent damage to the dryer tool 10 and the ring-shaped bearing 550, a maximum temperature limit, such as 90 degrees Celsius, can be set. The controller 118 (see FIGS. 2A-2C) can be programmed to send an over-temperature interlock signal to the heater 114 to stop (or halting) heating once the temperature exceeds (or reaches) this limit, thereby preventing any overheating and damage to the components of the dryer tool 10. This temperature control feature can ensure the efficient and safe operation of the dryer tool 10, allowing for consistent and reliable results while minimizing the risk of damage or failure due to excessive temperatures. In some embodiments, the thermocouple 116 can be interchangeably referred to as a thermometer.

The relationship between the pressure drop and time can be represented by a curve C7 as shown in FIG. 3C, which shows that the pressure drops more rapidly as with turning the ring-shaped bearing 550 and the heating time increases. In some embodiments, the combination of turning the ring-shaped bearing 550 and heating it in the dryer tool 10 can significantly reduce the drying time by 70% compared to the original of drying without turning and heating. This is because the turning of the ring-shaped bearing 550 promotes the evaporation of excess lubricant/grease and allows it to spread evenly on the surface of the ring-shaped bearing 550, while the heating increases the temperature of the lubricant/grease and accelerates the evaporation process. Once the desired pressure is achieved, the ring-shaped bearing 550 can be loaded into the buffer chamber 32 with the desired amount of lubricant/grease remaining on the ring-shaped bearing 550. This can help to increase the efficiency of the process and reduce the time required for maintenance and repair of the vacuum processing system 30. By way of example and not limitation, the drying process is performed in a drying time duration in a range from about 8 hours to about 48 hours, such as about 8, 10, 12, 14, 16,18, 20, 22, 24, 26, 28, 30, 32, 34, 36 hours. In some embodiments, the chamber 100 is evacuated in a drying time duration I having successive first, second, and third time intervals I1, I2, and I3. The second time interval I2 can have a greater pressure drop rate than the first and third time intervals I1 and I3. The pressure drop rate used as a signal to stop the drying process is calculated based on the pressure detected or obtained from the third time interval 13.

The pressure drop rate monitored in the dryer tool 10 can be used to judge the status of the ring-shaped bearing 550 because it is an indicator of the amount of excess lubricant/grease that needs to be removed before loading the ring-shaped bearing 550 into the buffer chamber 32. When the ring-shaped bearing 550 is placed in the buffer chamber 32, it will be subjected to a vacuum environment, which can cause the excess lubricant/grease to evaporate and contaminate the chamber. Therefore, it is necessary to ensure that the ring-shaped bearing 550 has been properly dried before being loaded into the buffer chamber 32. The pressure drop rate in the dryer tool 10 is related to the amount of excess lubricant/grease on the ring-shaped bearing 550. If there is a large amount of excess lubricant, it will take longer for the pressure to stabilize and the pressure drop rate will be slower in the early stages of the drying process. Conversely, if there is a small amount of excess lubricant, the pressure will stabilize more quickly, and the pressure drop rate will be faster. Therefore, by monitoring the pressure drop rate, it is possible to determine the amount of excess lubricant/grease on the ring-shaped bearing 550 and whether it has been sufficiently dried.

The controller 118 is configured to calculate the pressure drop rate. By way of example and not limitation, to ensure the ring-shaped bearing 550 has been sufficiently dried, a pressure drop threshold can be set. The controller 118 can be electrically connected to the pump 108, the motor 104, and the heater 114 and be programmed to send a signal to the pump 108, the motor 104, and the heater 114 to stop (or halting) performing the drying process once the pressure drop rate exceeds (or reaches) this limit, thereby ensuring that the ring-shaped bearing 550 has been sufficiently dried. In some embodiments, the pressure drop threshold can be in a range from about 2 to 20 mTorr per about 10 minutes, such as about 2, 3, 4, 5, 6, 7, 8, 9, 10, 11, 12, 13, 14, 15, 16, 17, 18, 19, or 20 mTorr per about 10 minutes, and the unit time can be in a range from about 5 to about 15 minutes, such as 5, 6, 7, 8, 9, 10, 11, 12, 13, 14, or 15 minutes. The pressure drop threshold can depend on various factors, such as the type of lubricant and the condition of the ring-shaped bearing 550.

Reference is made to FIGS. 2G and 2H. FIGS. 2G and 2H illustrate schematic cross-sectional views of dryer tools 60 and 70 with ring-shaped bearings corresponding to FIGS. 2A-2E. While FIGS. 2G and 2H show embodiments of the dryer tools 60 and 70 with different structure configurations than the dryer tool 10 in FIGS. 2A-2E. In addition, the present disclosure may repeat reference numerals and/or letters in the various examples. This repetition is for the purpose of simplicity and clarity and does not in itself dictate a relationship between the various embodiments and/or configurations discussed.

As shown in FIG. 2G, the difference between the embodiment in FIG. 2G and the embodiment in FIGS. 2A-2E is in that the cylindrically-shaped sidewall 602 has a greater height H2 (see FIG. 2G) than the height H1 (see FIG. 2E) of the cylindrically-shaped sidewall 102. Therefore, the cylindrically-shaped sidewall 602 can carry more ring-shaped bearings (e.g. about 4-12, such as about 4, 5, 6, 7, 8, 9, 10, 11, or 12) than the cylindrically-shaped sidewall 102, and can dry bearings 550 of different wafer handlers at the same time, which in turn increases the efficiency of the process and reduce the time required for maintenance and repair of multiple wafer handlers in the same vacuum processing system 30 or in the different vacuum processing systems 30.

As shown in FIG. 2H, the difference between the embodiment in FIG. 2G and the embodiment in FIGS. 2A-2E is in that the set 706a mounted on the motor 104 is located in cylindrically-shaped sidewall 102, such that the magnets 706a and 106b are arranged in such a way that they repel or attract each other in a same level height.

creating a non-contact rotation of the outer race 554. This arrangement allows the outer race 554 to rotate without making contact with the motor 104, thus achieving non-contact rotation. The non-contact rotation of the outer race 554 as shown in FIG. 2H can allow the lubricant/grease to spread more evenly, which accelerates the drying process and reduces the time required to remove excess lubricant.

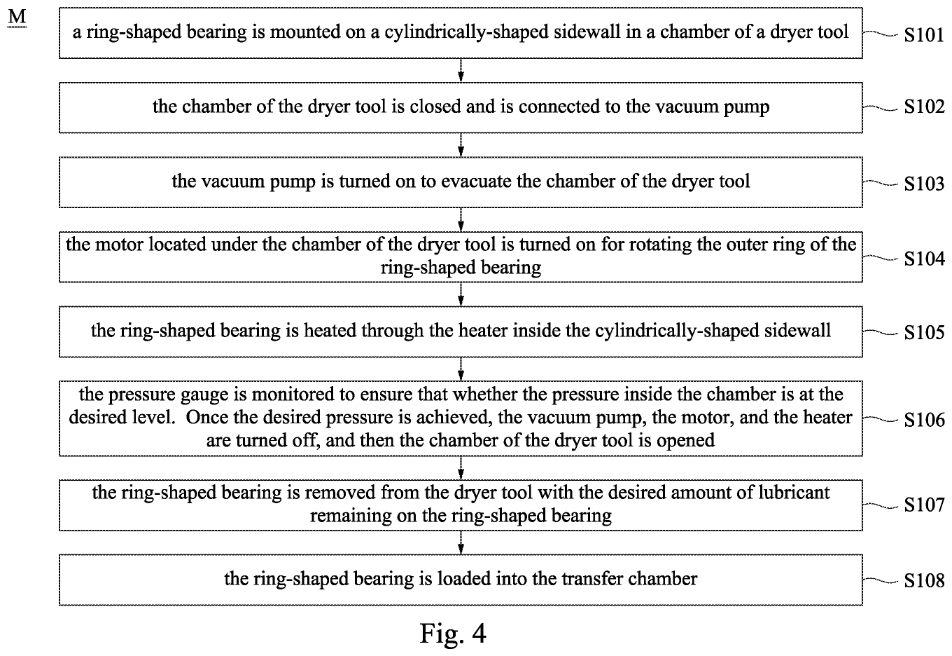

Reference is made to FIG. 4. FIG. 4 is a flowchart of a method M of using a dry tool to dry ring-shaped bearings with reference to FIGS. 2A-2E in accordance with some embodiments of the present disclosure. The method M includes a relevant part of the entire drying process. It is understood that additional operations may be provided before, during, and after the operations shown by FIG. 4, and some of the operations described below can be replaced or eliminated for additional embodiments of the method. The order of the operations/processes may be interchangeable. The method M includes drying a ring-shaped bearing. However, drying the ring-shaped bearing is merely an example for describing the drying process according to some embodiments of the present disclosure.

The method M begins at block S101. In some embodiments of block S101 with reference to FIGS. 2A-2E, the ring-shaped bearing 550 is mounted on the cylindrically-shaped sidewall 102 in the chamber 100 of the dryer tool 10.

The method M then proceeds to block S102, the chamber 10 of the dryer tool 10 is closed and is connected to the vacuum pump 108.

The method M then proceeds to block S103, the vacuum pump 108 is turned on to evacuate the chamber 100 of the dryer tool 10 to pre-simulate the pumping environment similar to the buffer chamber 32, allowing the excess lubricant/grease to be removed.

The method M then proceeds to block S104, the motor 104 located under the chamber 100 of the dryer tool 10 is turned on for rotating the outer race 554 of the ring-shaped bearing 550, which in turn causes the inner race 552 to remain fixed in place, enabling the outer race 554 to achieve non-contact rotation, resulting in a smooth and efficient rotation of the outer race 554. The non-contact rotation of the outer race 554 can allow the lubricant/grease to spread more evenly, which accelerates the drying process and reduces the time required to remove excess lubricant.

The method M then proceeds to block S105, the ring-shaped bearing 550 is heated through the heater 114 inside the cylindrically-shaped sidewall. When the ring-shaped bearing 550 is heated in the dryer tool 10, the temperature of the lubricant/grease inside the ring-shaped bearing 550 will increase, which will reduce its viscosity and increase its volatility. As a result, the lubricant/grease can be easily vaporized and removed, leading to a faster pressure drop compared to when the bearing is not heated. In some embodiments, the rotating and heating the ring-shaped bearing 550 are preformed simultaneously. In some embodiments, the rotating and heating the ring-shaped bearing 550 are preformed separately.

The method M then proceeds to block S106, the pressure gauge 112 is monitored to ensure that whether the pressure inside the chamber 100 is at the desired level. Once the desired pressure is achieved, the vacuum pump 112, the motor 104, and the heater 114 are turned off, and then the chamber 100 of the dryer tool 10 is opened. In some embodiments, the drying process can set a process end point (e.g. pressure drop threshold) based on the pressure drop rate calculated by the controller 118. Thereafter, the controller 118 can be programmed to send a signal to the pump 108, the motor 104, and the heater 114 to stop (or halting) performing the drying process once the pressure drop rate exceeds (or reaches) this limit, thereby ensuring that the ring-shaped bearing 550 has been sufficiently dried.

The method M then proceeds to block S107, the ring-shaped bearing 550 is removed from the dryer tool 10 with the desired amount of lubricant/grease remaining on the ring-shaped bearing 550.

The method M then proceeds to block S107, the ring-shaped bearing 550 is loaded into the buffer chamber 32.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a dryer tool that enables bearings to remove excess lubricant/grease before loading into the buffer chamber of a cluster tool. By doing so, the amount and duration of volatility of the bearings in the buffer chamber can be reduced, and then the buffer chamber can swiftly decrease pressure to reach the working pressure. Specifically, the dryer tool can create a pre-extraction environment for the bearing, which is similar to the buffer chamber of the vacuum processing system. This environment allows the lubricant/grease on the bearing to be vaporized by the dryer tool before the bearing is installed in the buffer chamber. Additionally, the dryer tool utilizes a technique of rotating and heating the bearing to expedite the volatilization of the lubricant/grease from the bearing, such that the dryer tool can help optimize the installation process and improve the performance of the buffer chamber.

In some embodiments, a method includes placing a ring-shaped bearing on a cylindrically-shaped sidewall in a chamber, the ring-shaped bearing comprising an inner race, an outer race, balls between the inner race and the outer race, and a grease among the balls; rotating the outer race of the ring-shaped bearing while the inner race of the ring-shaped bearing remains stationary relative to the cylindrically-shaped sidewall; heating the ring-shaped bearing; pumping the grease out of the chamber. In some embodiments, rotating the outer race of the ring-shaped bearing is performed by a contact-free manner. In some embodiments, rotating the outer race of the ring-shaped bearing is performed by a motor located outside of the chamber, wherein the motor comprises a first set of magnets on the chamber, and the outer race of the ring-shaped bearing comprises a second set of the magnets thereon, the second set of the magnets and the first set of the magnets are interact magnetically to allow rotation of the outer race when the motor is activated. In some embodiments, heating the ring-shaped bearing is performed by a heater installed on an inner surface of the cylindrically-shaped sidewall. In some embodiments, heating the ring-shaped bearing is performed at a temperature in a range from about 50 degrees Celsius to about 90 degrees Celsius. In some embodiments, the method further includes halting heating the ring-shaped bearing when the ring-shaped bearing has a temperature higher than about 90 degrees Celsius. In some embodiments, the grease is vaporized by the step of rotating the outer race, the step of heating the ring-shaped bearing, or a combination thereof. In some embodiments, the method further includes calculating a pressure drop rate within the chamber; determining whether the pressure drop rate within the chamber reaches a predetermined threshold; in response to the determination determines that the pressure drop rate within the chamber reaches the predetermined threshold, halting the step of the rotating the outer race of the ring-shaped bearing, the step of heating the ring-shaped bearing, and the step of pumping the grease. In some embodiments, the predetermined threshold is in a range from about 2 to about 20 mTorr per 10 minutes. In some embodiments, rotating the outer race of the ring-shaped bearing and heating the ring-shaped bearing are performed simultaneously.

In some embodiments, a method includes sleeving a first bearing to a cylinder in a chamber; after sleeving the first bearing to the cylinder, increasing a temperature of the first bearing; exhausting the chamber; detecting a pressure in the chamber during exhausting the chamber; calculating a pressure drop rate in the chamber based on the detected pressure; halting exhausting the chamber when the calculated pressure drop rate in the chamber exceeds a pressure drop threshold. In some embodiments, exhausting the chamber is performed in successive first, second, and third time intervals, the second time interval has a greater pressure drop rate than the first and third time intervals, and calculating the pressure drop rate in the chamber is performed in the third time interval. In some embodiments, the pressure drop threshold is lower than about 20 mTorr per 10 minutes. In some embodiments, the method further includes after sleeving the first bearing to the cylinder, sleeving a ring-shaped liner to the cylinder; after sleeving the ring-shaped liner to the cylinder, sleeving a second bearing to the cylinder. In some embodiments, the method further includes removing the first bearing from the chamber; after removing the first bearing, placing the first bearing between a magnet ring and a cylindrically-shaped sidewall of a wafer handler in a buffer chamber of a cluster tool.

In some embodiments, a dryer tool includes a vacuum chamber, a cylindrically-shaped sidewall, a motor, a plurality of magnets, and a pump. The cylindrically-shaped sidewall is in the vacuum chamber. The motor is located below the vacuum chamber. The magnets are mounted on the motor. From a top view, the magnets are around the cylindrically-shaped sidewall. The pump is in gas communication with the vacuum chamber. In some embodiments, the dryer tool further includes a heater on an inner surface of the cylindrically-shaped sidewall. In some embodiments, the dryer tool further includes a thermocouple on the cylindrically-shaped sidewall. In some embodiments, the dryer tool further includes a pressure gauge in gas communication with the vacuum chamber. In some embodiments, the dryer tool further includes a controller electrically connected to the pump and the motor and configured to activate the pump and activate the motor after activating the pump.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
placing a ring-shaped bearing on a cylindrically-shaped sidewall in a chamber, the ring-shaped bearing comprising an inner race, an outer race, balls between the inner race and the outer race, and a grease among the balls;
rotating the outer race of the ring-shaped bearing while the inner race of the ring-shaped bearing remains stationary relative to the cylindrically-shaped sidewall;
heating the ring-shaped bearing; and
pumping the grease out of the chamber.

2. The method of claim 1, wherein rotating the outer race of the ring-shaped bearing is performed by a contact-free manner.

3. The method of claim 1, wherein rotating the outer race of the ring-shaped bearing is performed by a motor located outside of the chamber, wherein the motor comprises a first set of magnets on the chamber, and the outer race of the ring-shaped bearing comprises a second set of the magnets thereon, the second set of the magnets and the first set of the magnets are interact magnetically to allow rotation of the outer race when the motor is activated.

4. The method of claim 1, wherein heating the ring-shaped bearing is performed by a heater installed on an inner surface of the cylindrically-shaped sidewall.

5. The method of claim 1, wherein heating the ring-shaped bearing is performed at a temperature in a range from about 50 degrees Celsius to about 90 degrees Celsius.

6. The method of claim 1, further comprising:
halting heating the ring-shaped bearing when the ring-shaped bearing has a temperature higher than about 90 degrees Celsius.

7. The method of claim 1, wherein the grease is vaporized by the step of rotating the outer race, the step of heating the ring-shaped bearing, or a combination thereof.

8. The method of claim 1, further comprising:
calculating a pressure drop rate within the chamber;
determining whether the pressure drop rate within the chamber reaches a predetermined threshold; and
in response to the determination determines that the pressure drop rate within the chamber reaches the predetermined threshold, halting the step of the rotating the outer race of the ring-shaped bearing, the step of heating the ring-shaped bearing, and the step of pumping the grease.

9. The method of claim 8, wherein the predetermined threshold is in a range from about 2 to about 20 mTorr per 10 minutes.

10. The method of claim 1, wherein rotating the outer race of the ring-shaped bearing and heating the ring-shaped bearing are performed simultaneously.

11. A method, comprising:
sleeving a first bearing to a cylinder in a chamber;
after sleeving the first bearing to the cylinder, increasing a temperature of the first bearing;
exhausting the chamber;
detecting a pressure in the chamber during exhausting the chamber;
calculating a pressure drop rate in the chamber based on the detected pressure; and
halting exhausting the chamber when the calculated pressure drop rate in the chamber exceeds a pressure drop threshold.

12. The method of claim 11, wherein exhausting the chamber is performed in successive first, second, and third time intervals, the second time interval has a greater pressure drop rate than the first and third time intervals, and calculating the pressure drop rate in the chamber is performed in the third time interval.

13. The method of claim 11, wherein the pressure drop threshold is lower than about 20 mTorr per 10 minutes.

14. The method of claim 11, further comprising:
after sleeving the first bearing to the cylinder, sleeving a ring-shaped liner to the cylinder; and
after sleeving the ring-shaped liner to the cylinder, sleeving a second bearing to the cylinder.

15. The method of claim 11, further comprising:
removing the first bearing from the chamber; and
after removing the first bearing, placing the first bearing between a magnet ring and a cylindrically-shaped sidewall of a wafer handler in a buffer chamber of a cluster tool.

16. A dryer tool, comprising:
a vacuum chamber;
a cylindrically-shaped sidewall in the vacuum chamber;
a motor located below the vacuum chamber;
a plurality of magnets mounted on the motor, wherein from a top view, the magnets are around the cylindrically-shaped sidewall; and
a pump in gas communication with the vacuum chamber.

17. The dryer tool of claim 16, further comprising:
a heater on an inner surface of the cylindrically-shaped sidewall.

18. The dryer tool of claim 16, further comprising:
a thermocouple on the cylindrically-shaped sidewall.

19. The dryer tool of claim 16, further comprising:
a pressure gauge in gas communication with the vacuum chamber.

20. The dryer tool of claim 16, further comprising:
a controller electrically connected to the pump and the motor and configured to activate the pump and activate the motor after activating the pump.
